(19) United States
(12) Patent Application Publication
(10) Pub. No.: US 2002/0064198 A1
(43) Pub. Date: May 30, 2002

(54) Semiconductor laser device having a circuit for protecting semiconductor laser element from static electricity

(76) Inventor: Hideshi Koizumi, Yamatotakada-shi (JP)

Correspondence Address: Barry E. Bretschneider, Morrison & Foerster LLP, Suite 5500, 2000 Pennsylvania Avenue, N.W., Washington, DC, 20006-1888, US

(21) Appl. No.: 09/993,709

(22) Filed: Nov. 27, 2001

(30) Foreign Application Priority Data
Nov. 27, 2000 (JP) 2000-359552

(51) Int. Cl. H01S 5/00

(52) U.S. Cl. 372/48

(57) ABSTRACT

A semiconductor laser device has a laser diode (LD) and an N-channel FET that are connected in parallel. In a normal state, an anode and a cathode of the LD are substantially short-circuited through the FET, so that almost of static electricity applied to a terminal connected to the LD flows to the FET and the LD is protected from static electricity. When driving the LD to emit light, a control signal of a negative potential is applied to a terminal connected to a gate of the FET to turn off the FET. With a driving current applied to the terminal connected to the LD, the driving current flows through the LD, which then emits light.

### BACKGROUND OF THE INVENTION

The present invention relates to a semiconductor laser device including a semiconductor laser element and a circuit for protecting the semiconductor laser element from static electricity.

The semiconductor laser element (laser diode) has a low electrostatic breakdown voltage, as compared with other elements. This is because the laser diode (hereinafter referred to as “LD”) itself is a single diode chip made of a material such as GaAlAs, and its structure is completely different from the structures of other types of elements. Further, when the LD is required to have high-speed responsiveness, its electrostatic capacitance is reduced, which is a factor of lowering of the electrostatic breakdown voltage.

If such an LD is mounted on an integrated circuit which is not provided with countermeasures against static electricity, or if terminals of the LD are drawn directly to the outside from the integrated circuit, then static electricity is easily applied to the LD, which results in the electrostatic breakdown of the LD.

For this reason, in the process of incorporating an LD into various electronic apparatuses, the greatest possible care is taken so that static electricity is not applied to the LD. For example, an LD is incorporated into an optical pickup that reads or writes information from/to an optical disc such as a compact disc and a videodisc, and the following countermeasures have been taken in the process of incorporating the LD: a soldering iron is connected to an earth so that leaked current dose not flow through the tip of the soldering iron; a worker is made to wear a grounding band so as to reduce a body potential of the worker; it is made sure that the worker does not directly touch not only the LD but also terminals of the LD. Also, it is required to take the greatest possible care of peripheral optical components as well.

On the other hand, a board to be connected to a LD may be formed with a circuit to protect the LD from static electricity, by using an element, such as a capacitor, a resistor and/or a coil.

FIG. 7 is an example of a conventional circuit. In this circuit, an LD 101 and a capacitor 102 are connected in parallel. The capacitance of the capacitor 102 is made to be sufficiently larger than that of the LD 101. For this reason, most of pulsed static electricity flows to the capacitor 102, whereby the LD 101 is protected from the static electricity.

FIG. 8 shows another conventional circuit. On a printed wiring board 111 is provided with terminals 112 and 113 to which an anode and a cathode of an LD (not shown) are respectively connected. These terminals 112 and 113 are connected to their wiring patterns 114 and 115, respectively. The wiring patterns 114 and 115 are short-circuited by a short circuiting pin and the like (not 110 shown). Thus, the anode and the cathode of the LD is short-circuited whereby the LD is protected from static electricity.

In the conventional circuit shown in FIG. 7, it is desirable to employ a capacitor having a large capacitance in an μF unit as the capacitor 102. However, it is difficult to use the capacitor having such a large capacitance. Further, when a high-frequency current is superposed on an input current of the LD (namely, high frequency modulation is performed on the input current) in order to reduce coherence of the LD, most of the high-frequency current disadvantageously flows to the capacitor 102.

Further, in the conventional circuit shown in FIG. 8, after connecting the LD to each of the terminals 112 and 113 of the printed wiring board 111, an operation to disconnect the wiring pattern 114 from the wiring pattern 115 is required. Also at this time as well, the greatest possible care is required as in the process of incorporating the LD, which was previously mentioned. Thus, it is required to carry out extremely complicated works or operations.

Although problems in the process of incorporating an LD have been mentioned so far, it should also be pointed out that the greatest possible care has been required also in the production process of an LD, namely, when mounting an LD on a mount or shipping the same. Thus, it has been essential to take countermeasures against static electricity with regard to the production control, assembling devices and the like.

### SUMMARY OF THE INVENTION

The present invention was made in view of the above problems, and an object thereof is to provide a semiconductor laser device which can protect an LD from static electricity and which can simplify the process of incorporating the LD and facilitates handling of the LD.

In order to accomplish the above object, the present invention provides a semiconductor laser device comprising:

a semiconductor laser element having an anode and a cathode; and

a switching element connected in parallel with the semiconductor laser element, the switching element establishing continuity between the anode and the cathode of the semiconductor laser element when the semiconductor laser device is in a non-operating state.

With this arrangement, since the continuity between the anode and the cathode of the semiconductor laser element is established by the switching element, most of the static electricity flows through the switching element, whereby the semiconductor laser element is protected from the static electricity.

In one embodiment, the switching element is a normally-on N-channel field effect transistor. This switching element is normally on to connect the anode and the cathode of the semiconductor laser element.

The present invention also provides a semiconductor laser device comprising:

a semiconductor laser element having an anode and a cathode;

a switching element connected in parallel with the semiconductor laser element; and

a means for turning on the switching element in response to a voltage between the anode and the cathode of the semiconductor laser element.

With this arrangement, the switching element is turned on in response to the voltage between the anode and the cathode of the semiconductor laser element, namely, across the semiconductor laser element so as to provide a connection between the anode and the cathode of the semiconductor laser element through the switching element. In this state, most of the static electricity flows to the switching element, whereby the semiconductor laser element is protected from the static electricity.

In one embodiment, the switching element is a normally-off P-channel field effect transistor.

Furthermore, the present invention provides a semiconductor laser device comprising:

a semiconductor laser element having an anode and a cathode; and

a switching element connected in series with the semiconductor laser element, the switching element being turned off when the semiconductor laser element is in a non-operating state.

With this arrangement, while the semiconductor laser element is in a non-operating state, since the switching element is off, an electric current does not flow to the semiconductor laser element. Thus, the semiconductor laser element is protected from the static electricity.

In one embodiment, the switching element is a normally-off N-channel field effect transistor. This switching element is off in its normal state so-as to block a path of electrical current to the semiconductor laser device.

Any of the switching elements described above may be housed in a package in which the semiconductor laser element is mounted.

Any of the switching elements described above may be integral with a heat sink on which the semiconductor laser element is mounted.

Also, any of the switching elements described above may be mounted on an integrated circuit for photodetection which includes the semiconductor laser element and a photodetector.

When the switching element is incorporated into the package, the heat sink or the integrated circuit for photodetection, the semiconductor laser element is protected from the static electricity in each case.

Furthermore, any of the switching elements described above may have an input terminal receiving a control signal for changing over the state of the switching element.

By changing over the state of the switching element through the control signal supplied to this input terminal, the electric current is allowed to flow through the semiconductor laser element, whereby the semiconductor laser element can be driven to emit light.

If the state of the switching element is changed over at the time of voltage application to the semiconductor laser element, an electric current flows through the semiconductor laser element only when required.

Other objects, features and advantages of the present invention will be obvious from the following description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a circuit diagram of a semiconductor laser device according to a first embodiment of the present invention;

FIG. 2 is a circuit diagram of a semiconductor laser device according to a second embodiment of the present invention;

FIG. 3 is a circuit diagram of a semiconductor laser device according to a third embodiment of the present invention;

FIG. 4 is a side view schematically showing an electronic component mounted with the semiconductor laser device according to any one of the first to third embodiments;

FIG. 5 is a side view schematically showing another electronic component mounted with the semiconductor laser device according to any one of the first to third embodiments;

FIGS. 6A and 6B show an integrated circuit for photodetection on which the semiconductor laser device according to any of the first to third embodiments of the present invention is mounted, where FIG. 6A is a side view with some parts omitted, while FIG. 6B is a plan view;

FIG. 7 is a circuit diagram showing a conventional semiconductor laser device; and

FIG. 8 illustrates a conventional printed wiring board on which a semiconductor laser element is to be mounted.

### DETAILED DESCRIPTION OF THE PREFERRED EMBODIMENTS

Embodiments of the present invention will hereinafter be described with reference to the accompanying drawings in which similar or same parts are denoted by same reference numerals.

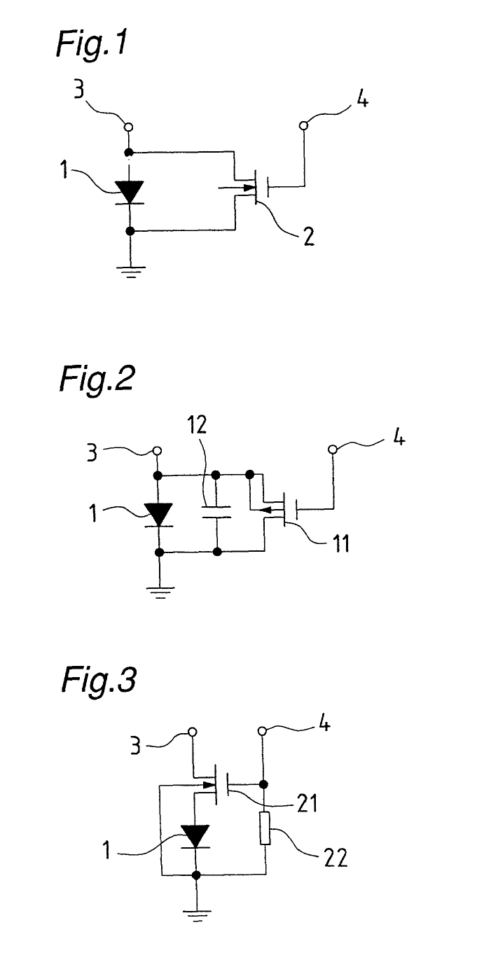

FIG. 1 is a circuit diagram showing a first embodiment of a semiconductor laser device according to the present invention. In the device of the first embodiment, a semiconductor laser element (hereinafter referred to as “LD”) 1 and a normally-on N-channel field effect transistor (hereinafter referred to as “N-channel FET” or simply “FET”) 2 are connected in parallel.

In the normal state, the N-channel FET 2 is on, so that an anode and a cathode of the LD 1 are substantially short-circuited through the FET 2. For this reason, even if static electricity is applied to a terminal 3, most of the static electricity flows through the FET 2, whereby the LED 1 is protected from the static electricity.

When the LD 1 is driven to emit light, a control voltage (negative potential) is applied to a terminal 4 connected to a gate of the FET 2 to turn off the FET 2. In this state, with a driving current supplied to the terminal 3, the driving current flows through the LD 1, whereby the LD 1 emits light.

FIG. 2 is a circuit diagram showing a second embodiment of a semiconductor laser device according to the present invention. In the device of the second embodiment, an LD 1, a normally-off P-channel FET (hereinafter referred to as “P-channel FET” or simply “FET”) 11, and a capacitor 12 are connected in parallel.

In the normal state, the P-channel FET 11 is off. When static electricity is applied to a terminal 3, the capacitor 12 is charged, so that the terminal voltage of the capacitor 12 increases. With an increase in the terminal voltage, a negative voltage comes to be applied to a gate of the FET 11 and the FET 11 is turned on. As a result, a short circuit is substantially established between an anode and a cathode of the LD 1 through the FET 11. Most of the static electricity from the terminal 3 flows through the FET 11, whereby the LED 1 is protected from the static electricity.

However, it is required that the FET 11 be turned on before terminal voltages of the LD 1 and the capacitor 12 reach the electrostatic breakdown voltage of the LD 1.

When the LD 1 is driven to emit light, a control voltage of a ground potential is applied to a terminal 4 connected to a gate of the FET 11 to turn it off. Then, a driving current from the terminal 3 flows through the LD 1, whereby the LD 1 emits light.

FIG. 3 is a circuit diagram showing a third embodiment of a semiconductor laser device according to the present invention. In the device of the third embodiment, an LD 1 and a normally-off N-channel FET 21 are connected in series, while the LD 1 and a resistor 22 are connected in parallel.

In the normal state, the N-channel FET 21 is off. For this reason, even if static electricity is applied to a terminal 3, an electric current does not flow through the LD 1, and thus the LD 1 is protected from the static electricity. Even if an electric current flows through the N-channel FET 21 in an off state, the resistance between a drain and a source of the FET 21 is high enough to sufficiently lower the voltage applied to the LD 1. As a result, the LD 1 is protected from the static electricity.

When driving the LD 1 to emit light, a control voltage of a positive potential is applied to the terminal 4 connected to the gate of the FET 11 to turn it on. Then, a driving current from the terminal 3 flows through the FET 11 to the LD 1 and the LD 1 emits light.

As the control voltage to be supplied to the terminal 4 to drive the LD 1, a voltage that is to be supplied from a voltage source to a driving circuit for the LD 1 may be applied. In that case, the FET 11 is turned on simultaneously with driving the LD 1.

In the first, second and third embodiments, passive elements and the like may be added as far as the operations of the individual circuits are not impaired. In FIGS. 1-3, parts similarly functioning are denoted by the same reference numerals.

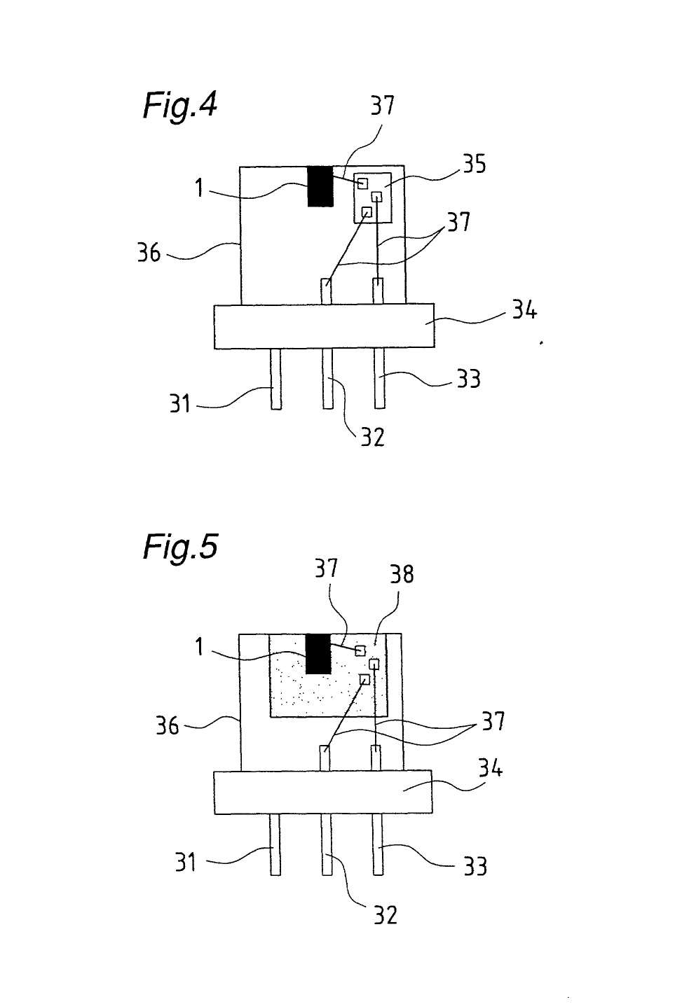

FIG. 4 shows an electronic component on which a semiconductor laser device according to any one of the first to third embodiments is mounted. In this electronic component, a stem 34 is provided with a ground pin 31, an input pin 32 corresponding to the terminal 3 in FIGS. 1 to 3, and a control pin 33 corresponding to the terminal 4 in FIGS. 1 to 3, while a columnar part 36, which is protrusively provided on the stem 34, is fitted with a printed wiring board 35 and an LD 1. A circuit on the printed wiring board 35 is connected to the LD 1, the input pin 32, the control pin 33 and the like through their respective wires (gold wires) 37, and the circuit together with the LD 1, the input pin 32 and the control pin 33 constitutes any one of the devices of the first to third embodiments. The electronic component is covered by a package that is not shown in the figure.

FIG. 5 shows another electronic component on which a semiconductor laser device according to any one of the first to third embodiments is mounted. In this electronic component as well, a stem 34 is provided with a ground pin 31, an input pin 32 and a control pin 33. Further, a columnar part 36, which is protrusively provided on the stem 34, is fitted with a heat sink 38. An LD 1 is mounted on the heat sink 38. The heat sink 38 is made of silicon, and a circuit is formed inside of the heat sink 38. The circuit in the inside of the heat sink 38 is connected to the LD 1, the input pin 32 and the control pin 33 and the like through respective wires 37, and constitutes the device according to any one of the first to third embodiments in association with the LD 1, the input pin 32, and the control pin 33. This electronic component is covered with a package that is not shown in the figure.

In FIGS. 4 and 5, those parts having the same functions are identified with the same numerals.

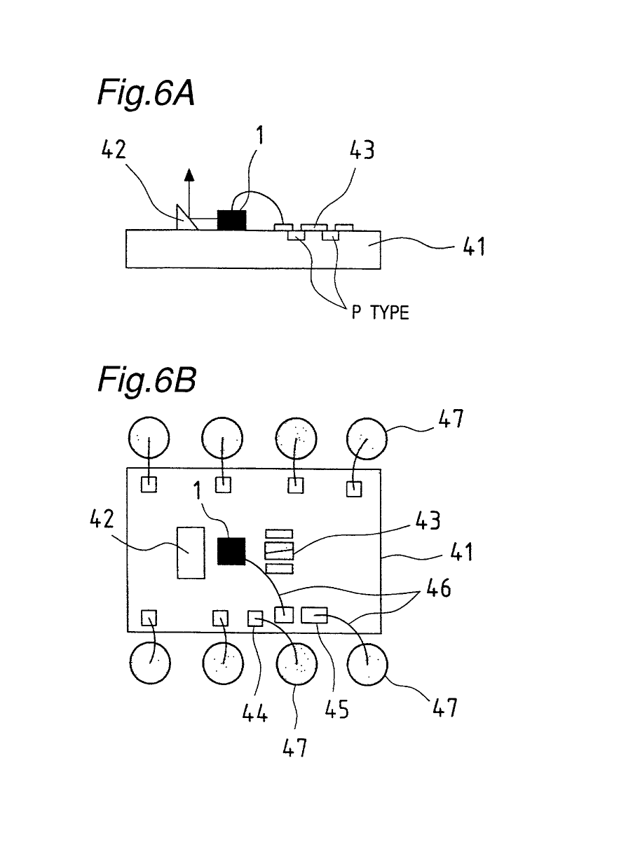

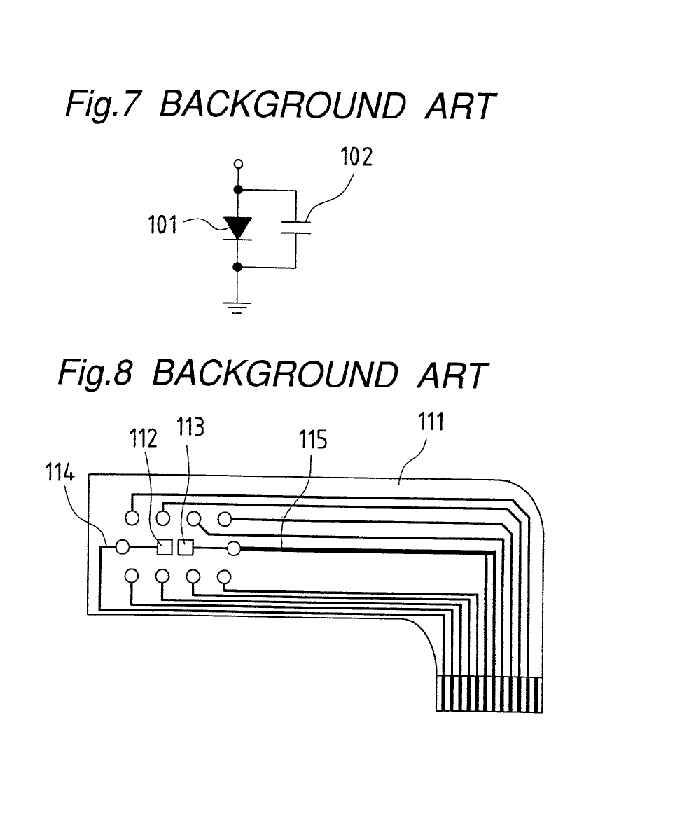

FIGS. 6A and 6B show an integrated circuit for photodetection on which a semiconductor laser device according to any one of the first to third embodiments is mounted. FIG. 6A is a side view of the integrated circuit for photodetection, while FIG. 6B is a plan view of the integrated circuit for photodetection.

This integrated circuit for photodetection is to be incorporated into an optical pickup that reads or writes information from/to an optical disc such as a compact disc and a videodisc. The integrated circuit for photodetection irradiates an optical disc with laser beams and receives light reflected on the optical disc to convert the light into electrical signals.

In the integrated circuit for photodetection, provided on a semiconductor chip 41 are an LD 1, a mirror 42 that reflects laser beams emitted from the LD 1 toward the direction of an optical disc, a photodetector 43 that receives light reflected on the optical disc and converts the light into electrical signals, an input electrode 44 corresponding to the terminal 3 in FIGS. 1 to 3, and a control electrode 45 corresponding to the terminal 4 in FIGS. 1 to 3. The input electrode 44, the control electrode 45 and the other electrodes are connected to their respective external terminals 47 through wires 46. Further, the semiconductor chip 41 is formed with a circuit. 20 The circuit within the semiconductor chip 41 is connected to the LD 1, the input electrode 44, the control electrode 45 and the like, and constitutes the device according to any one of the first to third embodiments together with the LD 1, the input electrode 44 and the control electrode 45.

When incorporating the device according to the third embodiment in the integrated circuit for photodetection, a power supply voltage for the integrated circuit may be used as the control voltage of the control electrode 45. In such a case, the FET 21 is allowed to be turned on simultaneously with the startup of the integrated circuit, so that a driving current is supplied to the LD 1 through the input electrode 44 to drive the LD 1 to emit light.

An operation of incorporating the device according to any one of the first to third embodiments in the electronic components of FIGS. 4 and 5 and the integrated circuit for photodetection of FIG. 6 is completed at the time of completion of the connection by the respective wires, at which time preventive measures against electrostatic breakdown of the LD 1 are also completed. After this process, since the LD 1 is protected from static electricity, the occurrence frequency of the electrostatic breakdown is markedly reduced. Therefore, in the process steps for incorporating these electronic components and the photodetection integrated circuit in electronic equipment, it is not necessary to be particularly careful about the electrostatic breakdown of the LD, whereby control of the working environment becomes easy. For example, unlike the conventional art, the operation for short-circuiting the anode and the cathode of the LD using wiring patterns or disconnecting the continuity therebetween is not required, and thus large-scale preventive measures against static electricity are not required. Further, damage to the LD due to static electricity is prevented, thus making it possible to prevent deterioration in the properties of the LD.

If an LD and a circuit are incorporated in a heat sink so as to provide preventive measures against electrostatic breakdown as in the electronic component shown in FIG. 5, it is possible to provide this heat sink per se as a product. This makes it possible to realize a product form close to a bare chip, which was previously thought difficult to produce.

The present invention is not limited to the above-mentioned embodiments, and can be modified in various ways. For example, various kinds of FETs can be applied and further other types of switching elements may be applicable.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device comprising:
a semiconductor laser element having an anode and a cathode; and
a switching element connected in parallel with the semiconductor laser element,
the switching element establishing continuity between the anode and the cathode of the semiconductor laser element when the semiconductor laser element is in a non-operating state.

2. The semiconductor laser device according to claim 1, wherein the switching element is a normally-on N-channel field effect transistor.

3. A semiconductor laser device comprising:
a semiconductor laser element having an anode and a cathode;
a switching element connected in parallel with the semiconductor laser element; and
a means for turning on the switching element in response to a voltage between the anode and the cathode of the semiconductor laser element.

4. The semiconductor laser device according to claim 3, wherein the switching element is a normally-off P-channel field effect transistor.

5. A semiconductor laser device comprising:
a semiconductor laser element having an anode and a cathode; and
a switching element connected in series with the semiconductor laser element, the switching element being turned off when the semiconductor laser device is in a non-operating state.

6. The semiconductor laser device according to claim 5, wherein the switching element is a normally-off N-channel field effect transistor.

7. The semiconductor laser device according to claim 1, wherein the switching element is housed in a package mounted with the semiconductor laser element.

8. The semiconductor laser device according to claim 1, wherein the switching element is integral with a heat sink on which the semiconductor laser element is mounted.

9. The semiconductor laser device according to claim 1, wherein the switching element is mounted on an integrated circuit for photodetection which includes the semiconductor laser element and a photodetector.

10. The semiconductor laser device according to claim 1, wherein the switching element has an input terminal receiving a control signal for changing over the state of the switching element.

11. The semiconductor laser device according to claim 1, wherein the state of the switching element is changed over through an input terminal at the time of voltage application to the semiconductor laser element.

12. The semiconductor laser device according to claim 3, wherein the switching element is housed in a package mounted with the semiconductor laser element.

13. The semiconductor laser device according to claim 3, wherein the switching element is integral with a heat sink on which the semiconductor laser element is mounted.

14. The semiconductor laser device according to claim 3, wherein the switching element is mounted on an integrated circuit for photodetection which includes the semiconductor laser element and a photodetector.

15. The semiconductor laser device according to claim 3, wherein the switching element has an input terminal receiving a control signal for changing over the state of the switching element.

16. The semiconductor laser device according to claim 3, wherein the state of the switching element is changed over through an input terminal at the time of voltage application to the semiconductor laser element.

17. The semiconductor laser device according to claim 5, wherein the switching element is housed in a package in which the semiconductor laser element is mounted.

18. The semiconductor laser device according to claim 5, wherein the switching element is integral with a heat sink on which the semiconductor laser element is mounted.

19. The semiconductor laser device according to claim 5, wherein the switching element is mounted on an integrated circuit for photodetection which includes the semiconductor laser element and a photodetector.

20. The semiconductor laser device according to claim 5, wherein the switching element has an input terminal receiving a control signal for changing over the state of the switching element.

21. The semiconductor laser device according to claim 5, wherein the state of the switching element is changed over through an input terminal at the time of voltage application to the semiconductor laser element.
